(19) United States
(12) Patent Application Publication
(10) Pub. No.: US 2024/0347500 A1
(43) Pub. Date: Oct. 17, 2024

(54) WIRE PATH PLATE HAVING ENHANCED DURABILITY FOR WIRE BONDING

(71) Applicant: ASMPT Singapore Pte. Ltd., Singapre (SG)

(72) Inventors: Keng Yew SONG, Singapore (SG); Yue ZHANG, Singapore (SG); Chonghao CHEN, Singapore (SG); Heqing CHEN, Singapore (SG)

(21) Appl. No.: 18/133,565

(22) Filed: Apr. 12, 2023

(51) Int. Cl. H01L 23/00

(52) U.S. Cl. CPC H01L 24/78; H01L 2224/78611

(57) ABSTRACT

A wire path plate for a wire bonding apparatus includes a first conductive plate coupled to a second conductive plate. Each conductive plate has an upper portion, a lower portion and a middle portion located between the upper and lower portions. A bonding wire is configured to be passed through a gap formed between the first and second conductive plates. At least one non-conductive strip is mounted along the upper and/or lower portions of at least one of the conductive plates for insulating the bonding wire from conductive surfaces of the at least one conductive plate at the position of the at least one non-conductive strip.

### FIELD OF THE INVENTION

The invention relates to the bonding of conductive wires onto semiconductor components, and in particular to a wire path plate for an apparatus adapted for conducting wire bonding operations.

### BACKGROUND AND PRIOR ART

Wire bonding is a critical process in semiconductor assembly that enables electrical connections to be made between a semiconductor die and a substrate on which the semiconductor die is mounted in order to form a semiconductor package. In the process of wire bonding, thin wires made of gold, copper or aluminum are used to connect bonding pads on the semiconductor die to those on the substrate in the semiconductor package. This process is used in a wide range of electronic devices, including microprocessors, memory chips, sensors, and other integrated circuits.

In particular, ball bonding is a wire bonding technique in which a small ball of metal is formed at the end of the wire and used to create the wire bond. The process involves creating a small ball of metal at the end of the wire held by a capillary, heating the ball to soften it, and then pressing it onto the bonding pad with the capillary. The pressure and heat cause the ball to bond with the bonding pad, and the wire is then bonded to the substrate.

The quality of the wire bond has a significant impact on the performance and reliability of the finished product. One of the challenges in wire bonding is to ensure that the wire bond is strong and reliable over time. In order to form the wire bonds consistently, the wire bonding process must be performed with a high degree of repeatability. Moreover, factors such as wire diameter, bonding temperature, bonding force, and material composition can all affect the strength and reliability of the wire bond.

FIG. 1 is a schematic side view of a conventional wire bonding apparatus 10 including a wire path plate 28. The wire bonding apparatus 10 has a wire spool holder 12 on which a wire spool 14 containing bonding wire 16 is mounted. The bonding wire 16 is pulled and fed from the wire spool 14 and is guided along its path by a wire guiding pole 18 towards the wire path plate 28.

The bonding wire 16 is passed through a gap in the wire path plate 28 and is threaded through an air tensioner body 22, which provides air pressure for exerting a downwards pulling force on the bonding wire 16. Thereafter, the bonding wire 16 is threaded through a capillary 20, where wire bonding operations are conducted at a tip of the capillary 20. Between the air tensioner body 22 and the capillary 20 are an upper wire clamp 24 and lower wire clamp 26 that are operable to releasably grip and control feeding of the bonding wire 16. The upper and lower wire clamps 24, 26 cooperate to either feed the bonding wire 16 towards the capillary 20, or to pull the bonding wire 16 away from the capillary 20 to withdraw a length of bonding wire 16 extending from the tip of the capillary 20.

The wire path plate 28 is utilized to ensure repeatability and consistency when performing wire bonding operations. An air flow A is generated within the gap in the wire path plate to form a bend in the bonding wire 16 inside the wire path plate 28, so as to create some laxity and a constant tension in the bonding wire 16. This avoids excessive uncontrolled tension created at the position of the capillary 20, so that the feeding of bonding wire 16 can be reliably controlled particularly by the upper and lower wire clamps 24, 26.

There are two plates comprised in the wire path plate 28 located along the wire feeding path where the wire is fed through the gap between the two plates. FIG. 2 is a perspective view of one of the plates 100 comprised in a conventional wire path plate 28 of the prior art. The plate 100 includes a conductive plate 102 having a surface that is made of a metallic material or has a metallic coating. An air nozzle 104 is located at one end of the conductive plate 102 for introducing an air flow A onto the inner surface of the conductive plate 102.

A groove 106 is centrally-located on the conductive plate 102 to facilitate guiding of the air flow A. An upper conductive recess 108 and a lower conductive recess 110 minimize friction between the bonding wire 16 and top and bottom guiding surfaces of the conductive plate 102.

FIG. 3 is a side view of the plate of FIG. 2, including a bonding wire 16 that has been deflected by an air flow directed towards the bonding wire 16. When air is blown in through the air nozzle 104 into an air channel undercut 116 in the conductive plate 102, a predetermined wire bend 118 is created by deflection of the bonding wire 16. Thus, a wire buffer region is created by the bending of the bonding wire 16 which also generates a wire tension that is required to ensure reliable wire feeding with a predetermined tension in the bonding wire 16. Wire guiding stubs 112 protrude from the surface of the conductive plate 102 for guiding the bending of the bonding wire 16, so that the wire bend 118 is sustained within the wire path plate 28 in the course of wire bonding operations.

The plates 100 may be entirely made of a conductive material such as a metal, or are at least coated with a conductive coating, to allow electrical charges to flow through the conductive plates 102. Otherwise, static charges generated by the bonding wire 16 may cause dust to be attracted onto and adhere to the bonding wire 16, thus causing defects in the wire bonds that are subsequently formed. Furthermore, surfaces of the conductive plates 102 should be smooth to minimize friction between the bonding wire and the plates 100. Nevertheless, it has been found that the above arrangement creates certain problems.

One problem is that, during bonding operations, a high potential difference will cause an electrical current generated in the bonding wire 16 to pass from the bonding wire 16 to the conductive plates 102, which may cause sparking 120.

Contact between the bonding wire 16 and the conductive plates 102 also causes friction and a wire sticking effect, leading to unexpected variations in wire tension. Such friction as well as sparking 120 experienced between the wire and the wire path plate accelerate wearing on the metallic surfaces of the conductive plates 102 along the wire path.

In time, such wearing causes the formation of indents along the wire path, resulting in even more friction on the bonding wire 16 and makes the wire tension essentially uncontrollable. Therefore, it would be beneficial to implement a solution for avoiding at least some of the above shortcomings of the prior art.

### SUMMARY OF THE INVENTION

It is thus an object of the invention to seek to reduce wire sticking to the wire path plate and to maintain a surface smoothness on surfaces of the wire path plate, so as to enhance the durability thereof to improve wire bonding performance.

According to a first aspect of the invention, there is provided a wire path plate for a wire bonding apparatus, the wire path plate comprising: a first conductive plate coupled to a second conductive plate, each conductive plate comprising an upper portion, a lower portion and a middle portion located between the upper and lower portions; and a gap formed between the first and second conductive plates through which a bonding wire is configured to be passed; and at least one non-conductive strip mounted along the upper and/or lower portions of at least one of the conductive plates for insulating the bonding wire from conductive surfaces of the at least one conductive plate at the position of the at least one non-conductive strip.

According to a second aspect of the invention, there is provided a wire bonding apparatus comprising: a wire path plate including a first conductive plate coupled to a second conductive plate, each conductive plate comprising an upper portion, a lower portion and a middle portion located between the upper and lower portions; and a gap formed between the first and second conductive plates through which a bonding wire is configured to be passed; and at least one non-conductive strip mounted along the upper and/or lower portions of at least one of the conductive plates for insulating the bonding wire from conductive surfaces of the at least one conductive plate at the position of the at least one non-conductive strip.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

An exemplary bonding apparatus incorporating the invention will now be described with reference to the accompanying drawings, in which:

FIG. 1 is a schematic side view of a conventional wire bonding apparatus including a wire path plate;

FIG. 2 is a perspective view of one of the plates comprised in a conventional wire path plate of the prior art;

FIG. 3 is a side view of the plate of FIG. 2, including a bonding wire that has been deflected by an air flow directed towards the bonding wire;

FIG. 4 is a perspective view of a wire path plate according to the preferred embodiment of the invention;

FIG. 5 is a cross-sectional view of the wire path plate looking along line B-B of FIG. 4;

FIG. 6 is a side view of a first conductive plate comprised in the wire path plate of FIG. 4;

FIG. 7 is a side view of a second conductive plate which is assembled in use to the first conductive plate of FIG. 6 to form the wire path plate; and

FIG. 8 is a side view of the first conductive plate indicating some exemplary dimensions of the first conductive plate according to the preferred embodiment of the invention.

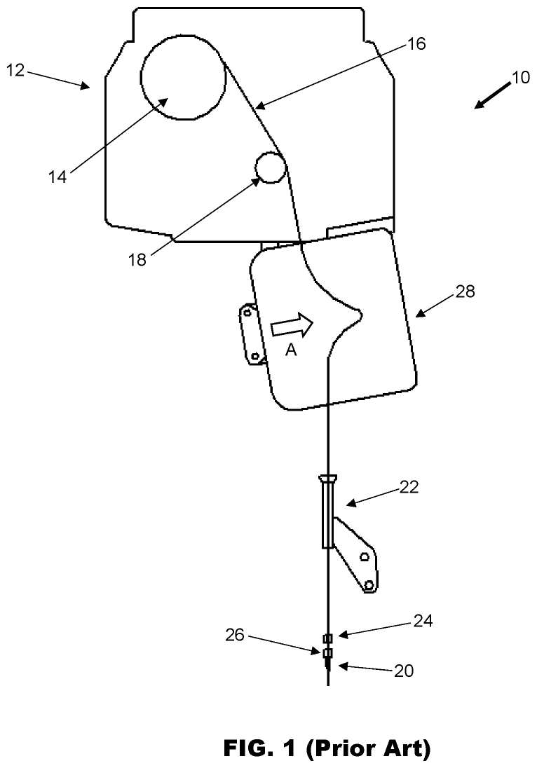

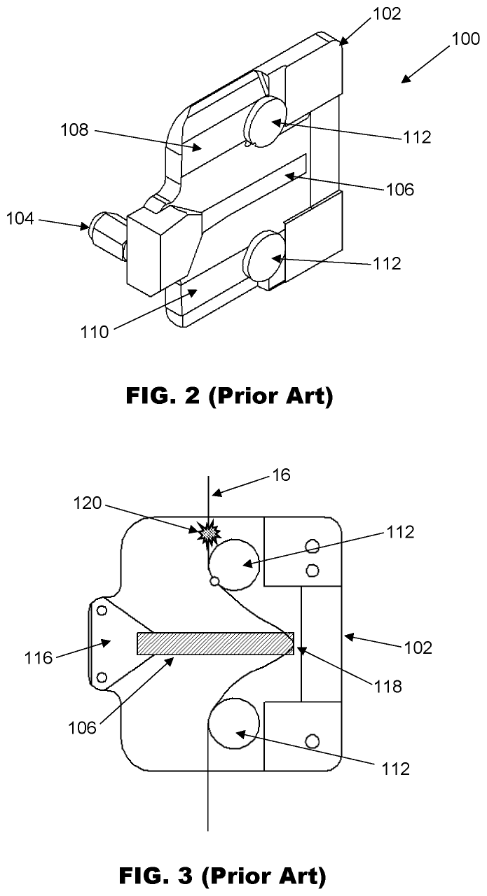

### DETAILED DESCRIPTION OF THE PREFERRED EMBODIMENT OF THE INVENTION

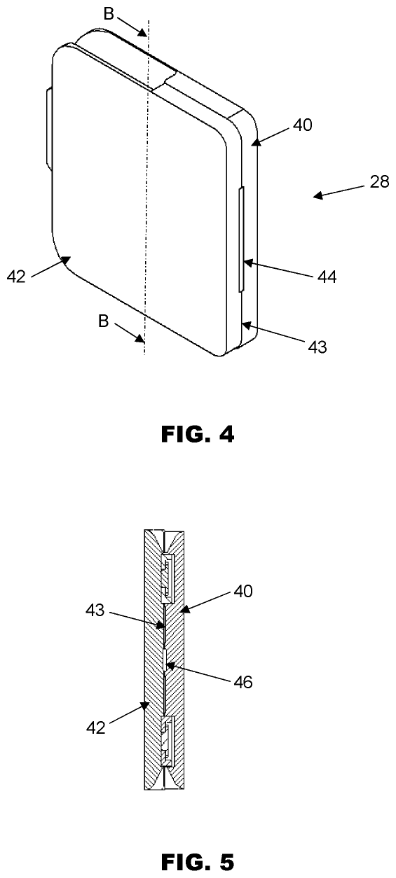

FIG. 4 is a perspective view of a wire path plate 28 according to the preferred embodiment of the invention that is installable on a wire bonding apparatus. The wire path plate 28 generally comprises a first conductive plate 40 and a second conductive plate 42, the first and second conductive plates 40, 42 being coupled to each other. When the first and second conductive plates 40, 42 are assembled together in use, a gap 43 is formed between the first and second conductive plates 40, 42 through which a bonding wire 16 is configured to be passed. An air channel undercut 44 is also illustrated whereat an air flow is introduced into the gap 43 between the first and second conductive plates 40, 42.

FIG. 5 is a cross-sectional view of the wire path plate looking along line B-B of FIG. 4. An air flow channel 46 is shown to be centrally located between the first and second conductive plates 40, 42.

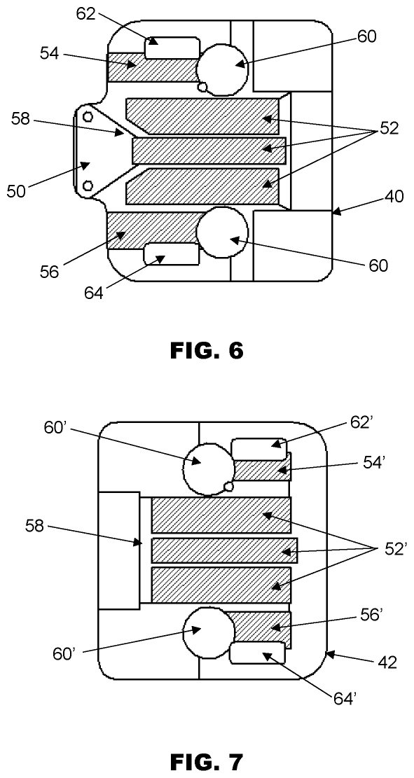

FIG. 6 is a side view of the first conductive plate 40 comprised in the wire path plate 28 of FIG. 4. Each conductive plate 40, 42 would have an upper portion, a lower portion and a middle portion located between the upper and lower portions. As can be seen, the first conductive plate 40 has an upper groove 54 formed on the upper portion of the first conductive plate 40, and a lower groove 56 formed on the lower portion of the first conductive plate 40, for minimizing contact between the bonding wire 16 and surfaces of the first conductive plate 40.

The first conductive plate 40 has an air channel undercut 50 for creating the air flow channel 46. The air channel undercut 50 is fluidly connected to an air nozzle 104 which introduces an air flow along the air channel undercut 50, and the air flow then passes along a plurality of middle grooves 52 arranged centrally across the middle portion of the first conductive plate 40. Preferably, the plurality of middle grooves 52 may include three rows of middle grooves 52. Therefore, an air channel 58 is formed from the three rows of middle grooves 52 formed longitudinally across the surface of the first conductive plate 40 in a direction of the air flow A for promoting deflection of the bonding wire 16.

First and second wire guiding stubs 60 protruding from the surfaces of the first conductive plate 40 are present for guiding the bending of the bonding wire 16 when the air flow A is introduced. The wire stubs 60 are configured with curved surfaces for guiding the bonding wire 16 to bend in the direction of the air flow A which is introduced into the gap 43. The middle portion of the first conductive plate 40 is defined by an area defined between the first and second wire guiding stubs 60. Accordingly, the three rows of middle grooves 52 are formed in the middle portion of the first conductive plate 40 between the respective wire guiding stubs 60.

In addition, at least one non-conductive strip is mounted along the upper and/or lower portions of the conductive plate 40 for insulating the bonding wire 16 from conductive surfaces of the conductive plate 40 at the position of the non-conductive strip. In the embodiment of the invention illustrated in FIG. 6, an upper non-conductive strip, which may be in the form of an upper non-conductive rod 62, is mounted adjacent to the upper groove 54. Further, a lower non-conductive strip or rod 64 is mounted adjacent to the lower groove 56. More preferably, the upper non-conductive rod 62, is mounted above the upper groove 54, and the lower non-conductive rod 64 is mounted below the lower groove 56. The upper and lower non-conductive rods 62, 64 serve to insulate the bonding wire 16 from the conductive surfaces of the first conductive plate 40 at the position of the upper and lower non-conductive rods 62, 64. The upper and lower non-conductive rods 62, 64 are preferably made of ceramic or sapphire.

Surprisingly, it has been found that such localized insulation is effective at preventing sparking between the bonding wire 16 and the conductive surfaces of the first conductive plate 40, while not adversely affecting the effectiveness of the wire bend 118 that is formed.

FIG. 7 is a side view of a second conductive plate 42 which is assembled in use to the first conductive plate 40 of FIG. 6 to form the wire path plate 28. The second conductive plate 42 correspondingly comprises three rows of middle grooves 52′ on its middle portion, which creates an air channel 58 along which an air flow A is generated. There is also an upper groove 54′ on its upper portion and a lower groove 56′ on its lower portion, and wire guiding stubs 60′ which mate with the wire guiding stubs 60 of the first conductive plate 42. These wire guiding stubs 60, 60′ form continuous curved surfaces for guiding the bonding wire 16 to bend.

Furthermore, there are corresponding upper and lower non-conductive rods 62′, 64′ mounted above the upper groove 54′ and below the lower groove 56′ respectively. These do not contact the upper and lower non-conductive rods 62, 64 of the first conductive plate 40, but instead, spaces are formed between each pair of non-conductive rods 62, 62′ and 64, 64′ for the bonding wire 16 to pass between the pair of upper non-conductive rods 62, 62′ and the pair of lower non-conductive rods 64, 64′ of the respective conductive plates 40, 42.

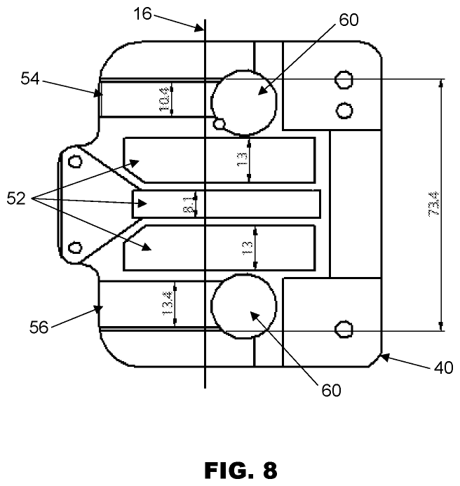

FIG. 8 is a side view of the first conductive plate 40 indicating some exemplary dimensions of the first conductive plate 40 according to the preferred embodiment of the invention. It can be seen that while a distance from a top end of the upper groove 54 to a bottom end of the lower groove 56 is 73.4 mm, a total length of the combination of widths of the upper, middle and lower grooves 52, 54, 56 is 57.9 mm (10.4 mm+13 mm+8.1 mm+13 mm+13.4 mm). Therefore, a total length of the combination of the widths of the grooves (from the top end of the upper groove 54 to the bottom end of the lower groove 56), for which the bonding wire 16 does not contact bases of the grooves in use, is about 79% of the distance from the top end of the upper groove 54 to the bottom end of the lower groove 56. Preferably, the percentage of the said surfaces of the first and second conductive plates 40, 42 covered by grooves is between 70% and 80% of the distance from the top end of the upper groove 54 to the bottom end of the lower groove 56. This would effectively limit the surfaces which cause friction and a wire sticking effect, as well as reduce the likelihood of the formation of unwanted indents in the surfaces arising from wear and tear.

It should thus be appreciated that, in the preferred embodiment of the invention, by introducing non-conductive rods 62, 64 at the upper and/or lower regions of the conductive plates 40, 42 where sparking 120 typically occurs, wear and tear on the surfaces that the bonding wire 16 passes through is greatly reduced, thereby maintaining superior surface smoothness even after a prolonged period of use of the wire path plate 28. By using non-conductive material such as ceramic or sapphire in the form of the non-conductive rods 62, 64 for specific areas on the wire path plate 28, a high degree of durability is therefore afforded.

Moreover, the wire path plate 28 is designed such that a contact area between the bonding wire 16 and the conductive plates 40, 42 of the wire path plate 28 is minimized, which reduces a tendency of wire sticking of the bonding wire 16 to the conductive plates 40, 42 from occurring.

The positive effects resulting from the preferred embodiments of the invention lead to the exponential extension of a life span of the wire path plate 28, which is currently only approximately 3 months. Another benefit is that the attraction of dust onto the bonding wire 16 due to static electricity is minimized. Therefore, looping performance and repeatability is greatly improved.

The invention described herein is susceptible to variations, modifications and/or additions other than those specifically described and it is to be understood that the invention includes all such variations, modifications and/or additions which fall within the spirit and scope of the above description.

1. A wire path plate for a wire bonding apparatus, the wire path plate comprising:
a first conductive plate coupled to a second conductive plate, each conductive plate comprising an upper portion, a lower portion and a middle portion located between the upper and lower portions;
a gap formed between the first and second conductive plates through which a bonding wire is configured to be passed; and
at least one non-conductive strip mounted along the upper and/or lower portions of at least one of the conductive plates for insulating the bonding wire from conductive surfaces of the at least one conductive plate at the position of the at least one non-conductive strip.

2. The wire path plate as claimed in claim 1, wherein the at least one non-conductive strip includes an upper non-conductive strip mounted along the upper portion of the at least one conductive plate.

3. The wire path plate as claimed in claim 2, wherein the at least one non-conductive strip further includes a lower non-conductive strip mounted along the lower portion of the at least one conductive plate.

4. The wire path plate as claimed in claim 1, further comprising at least one non-conductive strip correspondingly mounted on the other of the first and second conductive plates, wherein a pair of non-conductive strips comprising the at least one non-conductive strip of each of the first and second conductive plates facing each other form a space through which the bonding wire passes between the pair of non-conductive strips.

5. The wire path plate as claimed in claim 1, wherein the at least one conductive plate further comprises an upper groove formed along the upper portion of the conductive plate, a lower groove formed along the lower portion of the conductive plate and a plurality of middle grooves formed along the middle portion of the conductive plate.

6. The wire path plate as claimed in claim 5, further comprising an air channel undercut through with an air flow is introduced into the gap, wherein the plurality of middle grooves is formed longitudinally across a surface of the at least one conductive plate in a direction of the air flow.

7. The wire path plate as claimed in claim 5, including a first wire stub and a second wire stub protruding from a surface of the at least one conductive plate, wherein the plurality of middle grooves is located between the first and second wire stubs.

8. The wire path plate as claimed in claim 7, wherein the first and second wire stubs are configured with curved surfaces for guiding the bonding wire to bend in a direction of an air flow when the air flow is introduced into the gap.

9. The wire path plate as claimed in claim 5, wherein the middle portion includes three rows of middle grooves that are parallel to one another.

10. The wire path plate as claimed in claim 5, wherein a total length of a combination of widths of the upper, middle and lower grooves, for which the bonding wire is not configured to contact bases of the upper, middle and lower grooves in use, is between 70% and 80% of a distance from a top end of the upper groove to a bottom end of the lower groove.

11. The wire path plate as claimed in claim 5, wherein the at least one non-conductive strip comprises an upper non-conductive strip mounted adjacent to the upper groove of the at least one conductive plate.

12. The wire path plate as claimed in claim 11, wherein the upper non-conductive strip is mounted above the upper groove.

13. The wire path plate as claimed in claim 11, wherein the at least one non-conductive strip further comprises a lower non-conductive strip mounted adjacent to the lower groove of the at least one conductive plate.

14. The wire path plate as claimed in claim 11, wherein the lower non-conductive strip is mounted below the lower groove.

15. The wire path plate as claimed in claim 1, wherein the at least one non-conductive strip is made of ceramic or sapphire.

16. A wire bonding apparatus comprising:
a wire path plate including a first conductive plate coupled to a second conductive plate, each conductive plate comprising an upper portion, a lower portion and a middle portion located between the upper and lower portions;
a gap formed between the first and second conductive plates through which a bonding wire is configured to be passed; and
at least one non-conductive strip mounted along the upper and/or lower portions of at least one of the conductive plates for insulating the bonding wire from conductive surfaces of the at least one conductive plate at the position of the at least one non-conductive strip.
